(19) United States
(12) Patent Application Publication
(10) Pub. No.: US 2009/0130848 A1
(43) Pub. Date: May 21, 2009

(54) SEMICONDUCTOR DEVICE AND METHOD FOR PRODUCTION THEREOF

(75) Inventor: Eiji HASUNUMA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/355,014

(22) Filed: Jan. 16, 2009

(30) Foreign Application Priority Data
Oct. 26, 2005 (JP) 2005-311286
Aug. 14, 2006 (JP) 2006-221003

(51) Int. Cl. H01L 21/283

(52) U.S. Cl. 438/675; 257/E21.159

(57) ABSTRACT

A semiconductor device having a silicon substrate, an element isolating film, an active region, a gate electrode provided via a gate insulating film, a diffusion layer provided on the active region on opposite sides of the gate electrode, an interlayer insulating film, and a plug filled in a hole formed on the interlayer insulating film, wherein the semiconductor device further has a contact forming region surrounded by the element isolating film, and a conductive layer formed on the contact forming region, the gate electrode extends so as to overlap with a portion of the contact forming region and is connected to the conductive layer at the overlapping portion, and the plug contacts the conductive layer at another portion of the contact forming region and is electrically connected to the gate electrode via the conductive layer.

This is a divisional of application Ser. No. 11/585,165 filed Oct. 24, 2006, which claims priority from Japanese Patent Application Nos. 2005-311286 and 2006-221003 filed Oct. 26, 2005 and Aug. 14, 2006. The entire disclosures of the prior applications, are considered part of the disclosure of the accompanying divisional application and are hereby incorporated by reference.

### BACKGROUND OF THE INVENTION

1. Field of the Invention

The present invention relates to a semiconductor device and a method for production thereof, and relates particularly to a semiconductor integrated circuit device having a polymetal gate structure and a method for production thereof.

2. Description of the Related Art

In recent years, semiconductor integrated circuit devices, for example MPUs (microprocessors: micro processing units) for use in personal computers have had their computing speed improved by reducing the gate electrode width and increasing the drive frequency. The gate electrode width has been reduced by 30% in two years, and products having a wiring rule of 0.07 μm and a gate length of 0.03 μm have been developed.

The reduction of the gate length contributes not only to an improvement in characteristics but also to a reduction in the die area if the number of elements is the same. For example, by reducing the gate length by 30%, the die area decrease by half, and the quantity of dies produced from one substrate increases by a factor of 2.

However, when the gate length is reduced, the gate resistance increases, and in a conventional polycide gate, the gate resistance increases, and the element performance is deteriorated. For prevention of deterioration of the element performance, a gate (polymetal gate) having a laminated structure of polysilicon and a metal has been developed.

A method for production of a conventional field effect transistor (FET) having a polymetal gate structure will be described using the drawings.

FIG. 1 is a schematic plan view of a unit element of an FET constituting a semiconductor integrated circuit device. A region for forming FET elements (active region) and element isolating region 1 made of a silicon oxide film insulating and isolating the elements from one another are formed on a silicon substrate (not shown). On the active region, gate electrode 3 is formed via a gate insulating film (not shown), and gate contact 5 connected to an end portion of gate electrode 3 is provided. Source drain contact 4 connected to diffusion layer region 2 formed on the active region is provided.

FIGS. 2(a1) to 2(a4) and 2(b1) to 2(b4) are schematic process sectional views of FET elements, wherein FIGS. 2(a1) to 2(a4) are process sectional views taken along line A-A of FIG. 1 and FIGS. 2(b1) to 2(b4) are process sectional views taken along line B-B of FIG. 1.

Diffusion layer 11 as a source and a drain and element isolating film 12 composed of a silicon oxide film insulating and isolating elements from one another are formed on silicon substrate 10. On a channel region between diffusion layers 11, a gate electrode is formed via gate insulating film 13. This gate electrode has a laminated structure of polysilicon layer 14 and metal layer 15. Upper insulating film 16 is formed on this gate electrode, and side wall insulating film 17 is formed on the side surface of the gate electrode. Interlayer insulating film 18 is formed so as to cover the gate electrode on which upper insulating film 16 and side wall insulating film 17 are formed (FIG. 2(a1)).

FIG. 2(b1) shows a gate contact portion of a gate electrode end portion before formation of a contact. A gate electrode having a laminated structure of polysilicon layer 14 and metal layer 15 is formed on element isolating film 12 formed on silicon substrate 10. Upper insulating film 16 is formed on this gate electrode, side wall insulating film 17 is formed on the side surface of the gate electrode, and interlayer insulating film 18 is formed thereon.

After the structure described above is formed, a photoresist film (not shown) is formed on the entire surface of the substrate, and a normal photolithography method is used to remove a resist film portion corresponding to a portion on which hole 19 extending to diffusion layer 11 is formed. Dry etching is carried out using this photoresist film as a mask to form hole 19 extending diffusion layer 11 in interlayer insulating film 18, followed by removing the photoresist film (FIG. 2(a2)). The portion shown in FIG. 2(b2) still has the structure shown in FIG. 2(b1), since it is covered with the photoresist film.

Next, for forming a high-melting metal silicide on the exposed surface of diffusion layer 11, high-melting metal film 20 and Ti film 21 preventing oxidization of the high-melting metal film are continuously formed using a sputtering method. Then, a heat treatment is carried out to form high-melting metal silicide layer 22 on a portion of diffusion layer 11 contacted by the high-melting metal film (FIG. 2(a3), (b3)).

Unreacted high-melting metal film 20 and Ti film 21 thereon are removed by wet etching using an acidic solution of a mixed acid or the like, a photoresist film (not shown) is then formed on a substrate, and a normal photolithography method is used to remove a resist portion corresponding to a portion where hole 23 extending to the gate electrode is formed. Dry etching is carried out using this photoresist film as a mask to form hole 23 extending to the gate electrode, followed by removing the photoresist film.

Next, using a CVD (Chemical Vapor Deposition) method, a titanium nitride (TiN) film 24 as a barrier film and a tungsten (W) film 25 are continuously formed to fill holes 19 and 23 (FIGS. 2(a4) and 2(b4)).

Thereafter, the surface of the substrate is subjected to chemical mechanical polishing (CMP) to remove the W film and the TiN film outside the holes (not shown).

A technique concerning the contact structure of the polymetal gate electrode is disclosed in, for example, Japanese Patent Laid-Open No. 2001-127158. This publication discloses a structure in which for the purpose of reducing influences of the distribution interface resistance of the polymetal gate electrode and improving the operation speed of an MOS transistor, a lower end of a contact plug is connected to a polysilicon layer that forms a gate electrode lower layer portion through a metal layer that forms a gate electrode upper layer portion.

If a step of forming a hole for contact with a source-drain region and a step of forming a hole for contact with a gate electrode are separately carried out to form contacts, respectively, as described above, there is a problem of increasing the number of steps. However, if contacts are formed after forming both the holes formed for simplifying a production process, the following problem arises.

Cobalt is deposited as a high-melting metal, and a heat treatment is carried out to form a cobalt silicide on the surface of the diffusion layer of the bottom surface of a hole for source-drain contact. Thereafter, when excessive cobalt on a region where no silicide is formed is removed by wet etching, metal layer for gate 15 exposed at the bottom surface of a hole for formation of a gate contact is also etched, and a desired gate electrode cannot be formed.

### SUMMARY OF THE INVENTION

It is an object of the present invention to provide a semiconductor device capable of production with a simple process while having a polymetal gate structure and having a metal silicide layer for contact on a source-drain region, and a method for production thereof.

According to the present invention, there are provided the following semiconductor devices and methods for production thereof.

(1) A semiconductor device comprising:

a silicon substrate;

an element isolating film provided on the silicon substrate;

an active region surrounded by the element isolating film;

a gate electrode provided on the active region via a gate insulating film;

a diffusion layer provided on the active region on opposite sides of the gate electrode;

an interlayer insulating film provided over the silicon substrate; and

a plug filled in a hole formed in the interlayer insulating film,

wherein the semiconductor device further comprises a contact forming region surrounded by the element isolating film and a conductive layer formed on the contact forming region,

the gate electrode extends so as to overlap with a portion of the contact forming region and is connected to the conductive layer at the overlapping portion, and

the plug contacts the conductive layer at another portion of the contact forming region and is electrically connected to the gate electrode via the conductive layer.

(2) The semiconductor device according to item (1), wherein the gate electrode has a laminated structure including a polysilicon layer on the lower layer side and a metal layer on the upper layer side, and

the conductive layer is a metal silicide layer, and the metal silicide layer is connected to the polysilicon layer of the gate electrode.

(3) The semiconductor device according to item (1) or (2), wherein the conductive layer is a cobalt silicide layer.

(4) The semiconductor device according to any of items (1) to (3), wherein the contact forming region is covered in its entirety with an extending portion of the gate electrode and the plug.

(5) The semiconductor device according to item (4), wherein the gate electrode has an upper insulating film and a side wall insulating film for prevention of etching, which cover the upper part and the side wall of the gate electrode, and

the plug is formed by filling a conductive material in the hole which is formed such that the extending portion of the gate electrode covered with the upper insulating film and the side wall insulating film and the contact forming region are exposed.

(6) A method for production of a semiconductor device comprising:

a silicon substrate;

an element isolating film provided on the silicon substrate;

an active region surrounded by the element isolating film;

a gate electrode provided on the active region via a gate insulating film and having a laminated structure including a polysilicon layer on the lower layer side and a metal layer on the upper layer side;

a diffusion layer provided on the active region on opposite sides of the gate electrode;

an interlayer insulating film provided over the silicon substrate;

a first plug filled in a first hole formed in the interlayer insulating film, and electrically connected to the gate electrode; and

a second plug filled in a second hole formed in the interlayer insulating film, and electrically connected to the diffusion layer,

the method comprising the steps of:

preparing a silicon substrate having an element isolating region, an active region and a contact forming region;

forming a gate electrode provided on the active region via a gate insulating film and extending so as to overlap with a portion of the contact forming region via an insulating film;

introducing an impurity into the active region to form a diffusion layer;

forming an interlayer insulating film;

forming a first hole extending to another portion of the contact forming region and a second hole extending to the diffusion layer in the interlayer insulating film;

forming a metal film on at least the silicon substrate exposed surface of the bottom of the first hole and the second hole;

reacting the metal film with the silicon substrate by heating to form a metal silicide layer on the contact forming region and diffusion layer, and to connect the metal silicide layer formed on the contact forming region to the polysilicon layer lower surface side of the gate electrode extending portion overlapping with a portion of the contact forming region; and

filling a conductive material in the first hole and the second hole to form a first plug contacting the metal silicide layer on the contact forming region and a second plug contacting the metal silicide on the diffusion layer.

(7) A method for production of a semiconductor device comprising:

a silicon substrate;

an element isolating film provided on the silicon substrate;

an active region surrounded by the element isolating film;

a gate electrode provided on the active region via a gate insulating film and having a laminated structure including a polysilicon layer on the lower layer side and a metal layer on the upper layer side;

a diffusion layer provided on the active region on opposite sides of the gate electrode;

an interlayer insulating film provided over the silicon substrate;

a first plug filled in a first hole formed in the interlayer insulating film, and electrically connected to the gate electrode; and

a second plug filled in a second hole formed in the interlayer insulating film, and electrically connected to the diffusion layer,

the method comprising the steps of:

preparing a silicon substrate having an element isolating region, an active region and a contact forming region;

forming a gate electrode provided on the active region via a gate insulating film and extending so as to overlap with a portion of the contact forming region via an insulating film;

introducing an impurity into the active region to form a diffusion layer;

forming an interlayer insulating film;

forming a first hole extending to another portion of the contact forming region and a second hole extending to the diffusion layer in the interlayer insulating film;

forming a metal film on at least the silicon substrate exposed surface of the bottom of the first hole and the second hole;

reacting the metal film with the silicon substrate by first heating to form a metal silicide layer on the contact forming region and diffusion layer;

filling a conductive material in the first hole and the second hole to form a first plug contacting the metal silicide layer on the contact forming region and a second plug contacting the metal silicide on the diffusion layer; and

connecting the metal silicide layer formed on the contact forming region to the polysilicon layer lower surface side of the gate electrode extending portion overlapping with a portion of the contact forming region by second heating.

(8) The method for production of a semiconductor device according to item (6) or (7), wherein the metal film is a cobalt film, and the metal silicide layer is a cobalt silicide layer.

(9) The method for production of a semiconductor device according to any of items (6) to (8), wherein, in the step of forming the first hole and the second hole, the inner diameter of the first hole is made to be smaller than the inner diameter of the second hole so that an etching damage layer generated at the time of forming the first hole is left on the bottom of the hole and an etching damage layer on the bottom of the second hole generated at the time of forming the hole is removed in a chemical dry etching step that is subsequently carried out, and

the method further comprising the step of carrying out chemical dry etching to leave the etching damage layer on the bottom of the first hole and remove the etching damage layer on the bottom of the second hole after formation of the first hole and the second hole.

(10) The method for production of a semiconductor device according to any of items (6) to (9), wherein while the gate insulating film is formed on the active region, the insulating film is formed on the contact forming region, and the gate electrode extending so as to overlap with a portion of the contact forming region is formed via the insulating film.

(11) The method for production of a semiconductor device according to any of items (6) to (9), wherein the insulating film formed on the contact forming region is formed so as to be thinner than the gate insulating film formed on the active region, and the gate electrode extending so as to overlap with a portion of the contact forming region is formed via the thin insulating film.

According to the present invention, a semiconductor device capable of production with a simple process while having a polymetal gate structure and having a metal silicide layer for contact on a source-drain region, and a method for production thereof can be provided. In particular, according to the present invention, the gate contact is not connected directly to a metal layer that forms the gate electrode upper layer part, but connected to a polysilicon layer that forms the gate electrode lower layer part via a metal silicide formed on the surface of the substrate. Thus, even if holes for a gate contact and a source-drain contact are formed at the same time, a gate electrode structure can satisfactorily be formed, and resultantly, a semiconductor device excellent in element characteristics can be produced with a simplified process.

### BRIEF DESCRIPTION OF THE DRAWINGS

FIG. 1 is a schematic plan view of an FET element of a conventional semiconductor device;

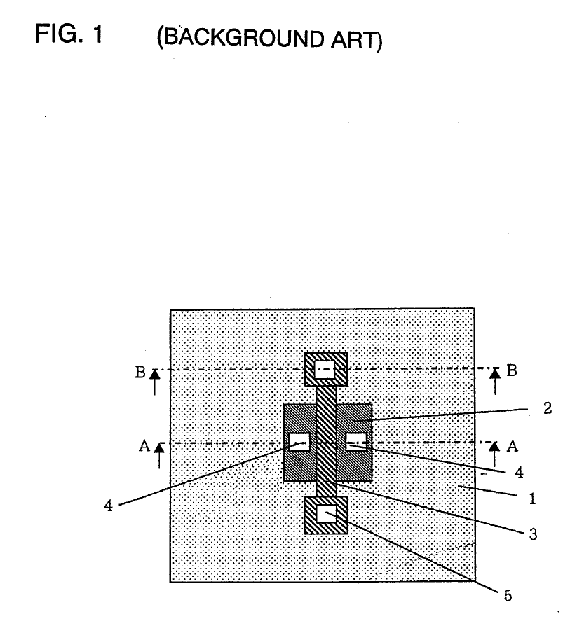

FIGS. 2(a1) to 2(a4) and 2(b1) to 2(b4) are schematic process sectional views showing a method for production of the conventional semiconductor device;

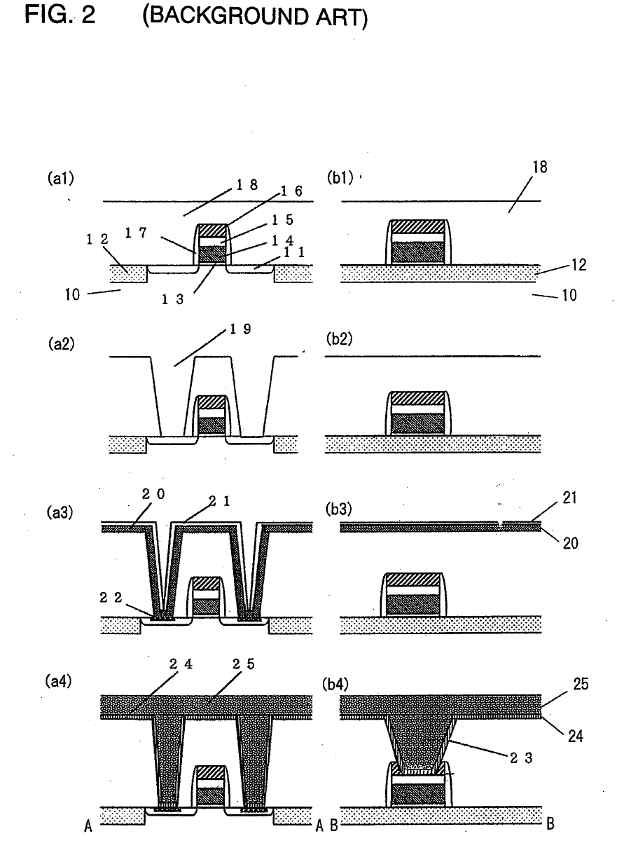

FIG. 3 is a schematic plan view of an FET element of a semiconductor device of the present invention;

FIGS. 4(a1) to 4(a4) and 4(b1) to 4(b4) are schematic process sectional views showing a method for production of the semiconductor device of the present invention;

FIGS. 5(a) and 5(b) are schematic sectional views for explaining a gate contact structure of the semiconductor device of the present invention;

FIGS. 6(a) and 6(b) are schematic sectional views for explaining the method for production of the semiconductor device of the present invention;

FIGS. 7(a) to 7(c) are schematic explanatory views for explaining the gate contact structure of the semiconductor device of the present invention; and

FIG. 8 is a schematic sectional view for explaining the gate contact structure of the semiconductor device of the present invention.

### DETAILED DESCRIPTION OF THE PREFERRED EMBODIMENTS

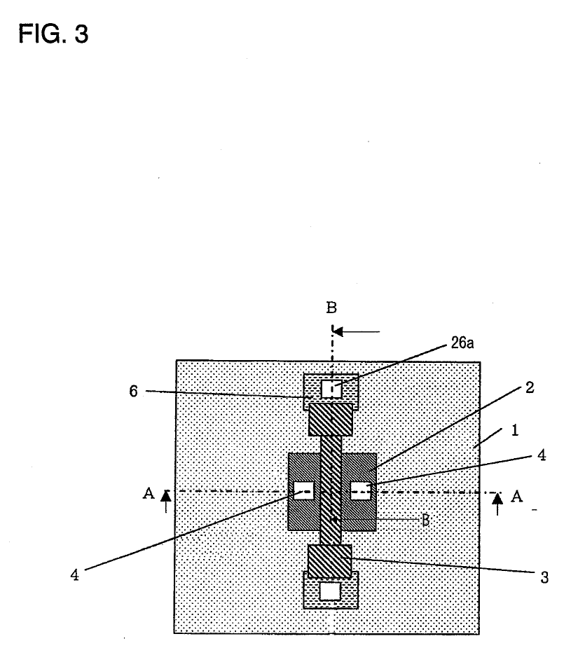

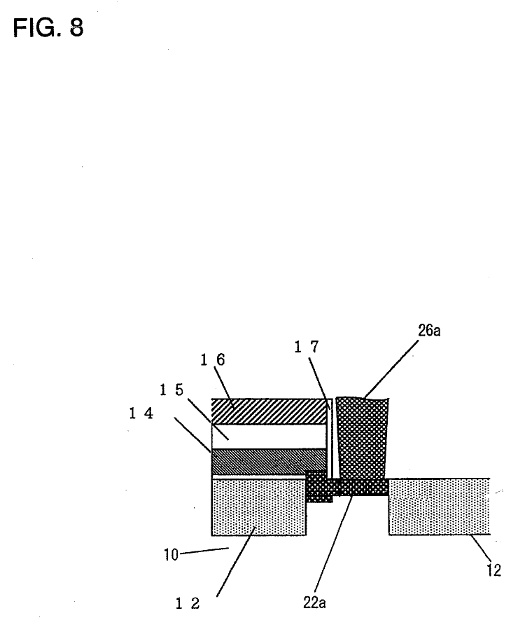

A gate contact structure electrically connecting a wiring formed above a gate electrode and the gate electrode in a semiconductor device of this embodiment will be described using FIGS. 3 and 8.

As shown in FIG. 8, the gate electrode has a laminated structure of polysilicon layer 14 and metal layer 15, upper insulating film (etching protective layer) 16 made of an insulating film is formed thereon, and side wall insulating film 17 is formed on the side surface. A barrier layer made of a metal nitride, or the like may be provided between the polysilicon layer and the metal layer in terms of improvement of adhesiveness and prevention of an increase in resistance. An impurity is introduced in the polysilicon layer for imparting conductivity.

As shown in FIGS. 3 and 8, the gate electrode extends to the top of element isolating region 1 (element isolating film 12) from the top of an active region for forming an FET element, and further, an end portion of the gate electrode reaches and partly overlaps with the top of contact forming region 6 (region of the exposed surface of the silicon substrate) surrounded by the element isolating film. In the figures, an end portion of a gate electrode extending portion in the longitudinal direction overlaps, but a side end portion of the gate electrode extending portion may overlap (not shown).

As shown in FIG. 8, contact plug 26a is provided for electrically connecting a wiring (not shown) formed on an interlayer insulating film and the gate electrode, and this contact plug 26a is connected to polysilicon layer 14 of the gate electrode via metal silicide 22a formed on a silicon substrate surface portion of contact forming region 6.

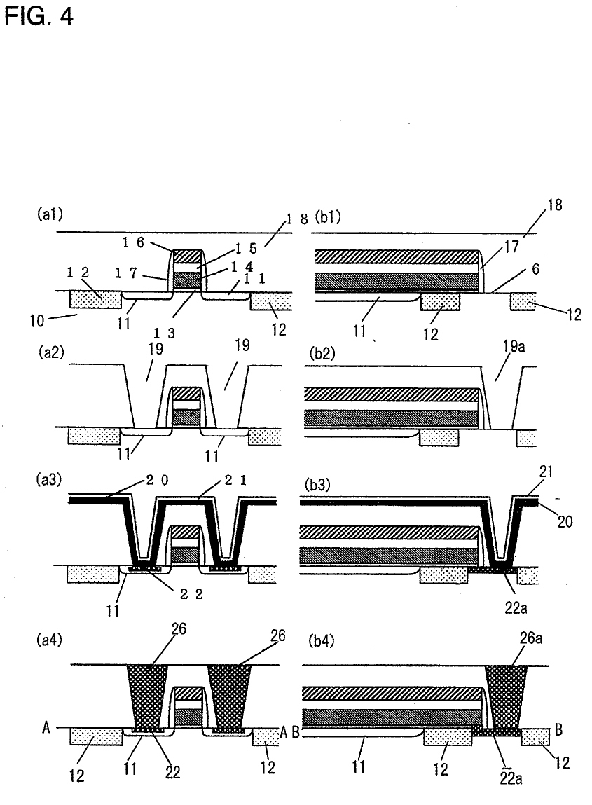

The first embodiment of the present invention will be further described using FIGS. 3 and 4(a1) to 4(a4) and 4(b1) to 4(b4).

FIG. 3 is a schematic plan view of a unit element of an FET constituting the semiconductor device of this embodiment. An active region for forming an FET element, element isolating region 1 and contact forming region 6 for forming a gate contact are formed on the silicon substrate. The gate electrode 3 extends to the top of the element isolating region from the top of the active region, and further, an end portion of gate electrode 3 reaches and partly overlaps with the top of contact forming region 6. Gate contact plug 26a is provided so as to contact the top surface of the substrate in the contact forming region. Diffusion layer region 2 as a source-drain region is formed on the active region, and source-drain contact 4 is provided on the region.

FIGS. 4(a1) to 4(a4) are process sectional views taken along line A-A of FIG. 3, and FIGS. 4(b1) to 4(b4) are process sectional views taken along line B-B of FIG. 3.

First, a structure having the FET element shown FIGS. 4(a1) and 4(b1) is formed on silicon substrate 10. Element isolating film 12, an active region where no element isolating film 12 is provided, and contact forming region 6 are formed on the silicon substrate. A gate electrode having a laminated structure of polysilicon layer 14 and metal layer 15 is formed on the active region via gate insulating film 13. Upper insulating film (etching protective layer) 16 and side wall insulating film 17 are formed on the top surface and the side surface of the gate electrode, respectively. Diffusion layer 11 as a source-drain region is formed on the silicon substrate on opposite sides of the gate electrode, and a channel is formed on a semiconductor layer portion below the gate electrode between diffusion layers 11 at the time of the operation of the FET. The gate electrode extends to the top of element isolating film 12 from the top of the active region, and further, a gate electrode end portion reaches the top of contact forming region 6. The gate electrode end portion is formed so as to cover a portion of contact forming region 6 surrounded by element isolating film 12 (element isolating region 1) as shown in FIG. 3. Interlayer insulating film 18 is formed on the entire surface so as to cover the gate electrode.

The structure described above can be fabricated in a manner described below. Silicon substrate 10 on which element isolating film 12 is formed is prepared, and a gate insulating film 13 made of a thermally oxidized film having a thickness of 5 nm is formed on the active region and the contact forming region using a thermal oxidization method. The thermally oxidized film may be subjected to a nitriding treatment to form a silicon oxy-nitride film.

Next, a polysilicon film having a thickness of 70 nm, a tungsten film having a thickness of 50 nm and silicon nitride film having a thickness of 150 nm are formed using a CVD method and a sputtering method. Molybdenum (Mo) having a high electro-migration resistance may be used instead of tungsten. An impurity is introduced into the polysilicon film by ion implantation after the film is formed.

Using a normal photolithography method and dry etching method, gate insulating film 13, the polysilicon film, the tungsten film and the silicon nitride film are processed to form a gate electrode. Thereafter, a silicon nitride film having a thickness of 20 nm is formed, and subsequently etched back by anisotropic dry etching to leave a silicon nitride film on the side wall of the gate electrode and remove a silicon nitride film on other portions to form side wall insulating film 17 made of the silicon nitride film.

Next, an impurity is introduced into the active region by ion implantation to form diffusion layer 11, using the gate electrode and the side wall insulating film as a mask. Thereafter, interlayer insulating film 18 made of a silicon oxide film having a thickness of 500 nm is formed using a normal CVD method.

After the structure shown in FIGS. 4(a1) and 4(b1) is obtained in a manner described above, a resist film for forming holes 19 and 19a is formed using a normal photolithography method. Interlayer insulating film 18 is dry-etched using the resist film as a mask to form hole 19 extending to diffusion layer 11 in the active region and hole 19a extending to the surface of silicon substrate 10 in contact forming region 6 (FIGS. 4(a2) and 4(b2)). The diameter Φ of an opening of a resist for forming hole 19 and hole 19a may be 140 nm.

Next, for forming a metal silicide on the surface of the silicon substrate exposed on the bottom of holes 19 and 19a, high-melting metal film 20 having a thickness of 20 nm and composed of cobalt, and Ti film 21 preventing oxidization of high-melting metal film 20 and having a thickness of 20 nm are continuously formed using a sputtering method. Thereafter, a heat treatment is carried out at 430° C. for 1 minute to form cobalt silicide layers 22 and 22a on the surface of diffusion layer 11 and the substrate surface of contact forming region 6 (FIGS. 4(a3) and 4(b3)).

Element isolating film 12 is formed on the periphery of the active region where the diffusion layer is formed, and similarly, element isolating film 12 is formed on the periphery of contact forming region 6 where gate contact plug 26a is formed. The active region has a dimension of about 800×800 nm, whereas contact forming region 6 has a dimension of about 200×200 nm, and is formed to have a reduced area. The silicon substrate and the insulating film for isolating elements have different materials, and therefore the silicon substrate in contact forming region 6 having a small area is under greater stress than the active region having a large area.

In one FET element unit, the area of the contact forming region surrounded by the element isolating film is preferably 25% or less, more preferably 15% or less, further preferably 10% or less of the area of the active region surrounded by the element isolating film in terms of generation of sufficient stress. The ratio of the area is 1% or more in terms of security of a sufficient contact region.

In thermal oxidization for formation of the gate insulating film, silicon substrate 10 is not only oxidized from its surface but also oxidized in the lateral direction via the element isolating film. Silicon is cubically expanded when oxidized, but since the element isolating film has no space for expansion and expansion proceeds toward the silicon side, a silicon region surrounded by the element isolating film is stressed.

The silicide formation reaction in which a high-melting metal such as cobalt reacts with silicon has an increased reaction rate when the silicon surface is stressed.

As a result, the reaction rate of the silicide formation reaction at contact forming region 6 is higher than that of the silicide reaction at diffusion layer 11, and the amount of cobalt silicide formed on contact forming region 6, namely the area of the silicide layer at the flat surface of the substrate is greater than the amount and the area of cobalt silicide formed on the diffusion layer.

Next, unreacted cobalt film 20 and Ti film 21 thereon are removed using a buffered fluoric acid solution, and a TiN film (not shown) as a barrier film having a thickness of 20 nm and a tungsten film having a thickness of 300 nm are then continuously formed using a CVD method to fill holes 19 and 19a. A mixed acid containing phosphoric acid, nitric acid, acetic acid and the like may be used instead of a buffered fluoric acid solution.

Subsequently, the tungsten film and the TiN film on the substrate surface are removed by a CMP method, and contact plugs 26 and 26a are formed.

Thereafter, the silicide formation reaction is made to further proceed by a heat treatment, cobalt silicide layer 22a formed on the contact forming region is thus grown to bring cobalt silicide layer 22a and polysilicon layer 14 into contact with each other, and the gate electrode and contact plug 26a are electrically connected via cobalt silicide layer 22a (FIG. 4(a4) and 4(b4)).

Here, the heat treatment for forming cobalt silicide layer 22a and the heat treatment for growing cobalt silicide layer 22a to connect cobalt silicide layer 22a and polysilicon layer 14 of the gate electrode are carried out separately, but by appropriately setting the thickness of the gate insulating film, the state of the surface of the silicon substrate and the conditions of the heat treatment, cobalt silicide layer 22a and polysilicon layer 14 may be connected at the time of the heat treatment for formation of cobalt silicide layer 22a. The heat treatment for connecting cobalt silicide layer 22a and polysilicon layer 14 may also be performed in a step carried out subsequently and involving heating, for example a step of forming a second interlayer insulating film (silicon oxide film, TEOS oxide film, etc.) and an etching stopper film formed on interlayer insulating film 18.

The conditions of the heat treatment for connecting cobalt silicide layer 22a and polysilicon layer 14 of the gate electrode may appropriately be set according to the thickness of the gate insulating film, the state of the surface of the silicon substrate which is subjected to silicide formation, the area of the contact forming region, and so on, but may be selected from, for example, the ranges of 300 to 800° C. and 1 to 20 minutes.

In the silicide formation reaction of silicon and a high-melting metal, a metal such as titanium suctions silicon upward the metal side, but cobalt is diffused in silicon to form a cobalt silicide.

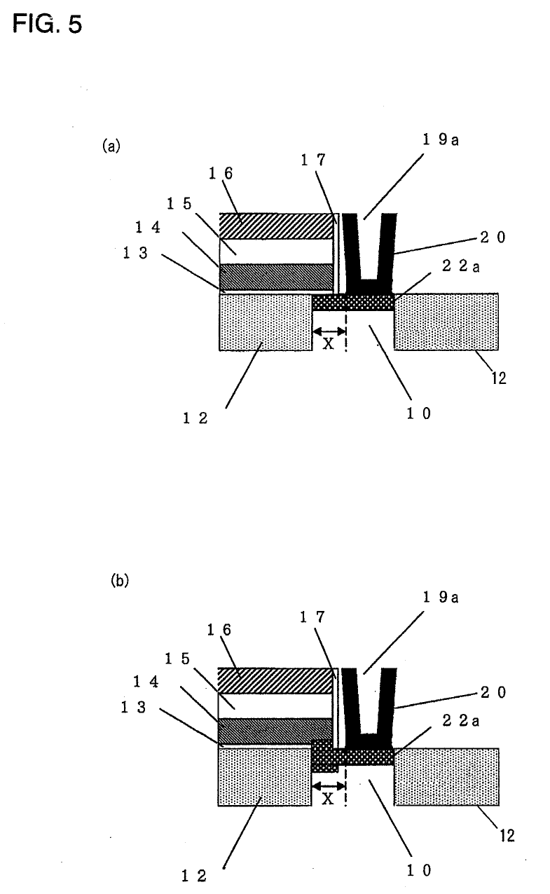

FIG. 5(a) shows a schematic sectional view of the enlarged contact forming region part of FIG. 4(b3), and FIG. 5(b) shows a schematic sectional view of a state after carrying out the heat treatment for connecting cobalt silicide layer 22a and polysilicon layer 14 of the gate electrode.

By the heat treatment for formation of the metal silicide, cobalt is diffused into the silicon substrate from a surface where cobalt film 20 and silicon substrate 10 contact each other, and cobalt silicide layer 22a is thereby formed (FIG. 5(a)). At this time, cobalt is diffused in a direction perpendicular to the substrate flat surface and a direction parallel to the substrate flat surface. Since a stress on the silicon substrate on the contact forming region is greater than a stress on the diffusion layer on the active region, the rate of the silicide formation reaction of the cobalt film provided in hole 19a and the silicon substrate is higher than the rate of the silicide formation reaction of the cobalt film provided in hole 19 and the silicon substrate (the amount of cobalt diffused into the silicon substrate is great). Further, since the contact forming region is narrow, and therefore, diffusion of cobalt in a direction parallel to the flat surface of the substrate in a region surrounded by the element isolating film quickly arrives at the element isolating film surrounding the contact forming region and stops.

Under the conditions of the heat treatment for connecting cobalt silicide layer 22a and polysilicon layer 14 of the gate electrode, cobalt in cobalt silicide layer 22a already formed is to be further diffused, but cannot be diffused in a direction parallel to the substrate flat surface due to the element isolating film. Therefore, the cobalt silicide formed below the end portion of the gate electrode (portion where the gate electrode and the contact forming region overlap with each other) breaks through a thin gate insulating film to contact polysilicon layer 14 of the gate electrode. Cobalt in the cobalt silicide is diffused into polysilicon layer 14, and a cobalt silicide is formed, and resultantly, cobalt silicide layer 22a and the gate electrode are connected (FIG. 5(b)).

When the cobalt silicide below the end portion of the gate electrode and the polysilicon layer of the gate electrode are connected, silicon in the gate insulating film interposed between the former and the latter reacts with cobalt in the cobalt silicide to form a cobalt silicide. Cobalt diffused into this cobalt silicide passes through the gate insulating film to react with silicon of the polysilicon layer of the gate electrode, and resultantly, the cobalt silicide breaks through the gate insulating film to connect cobalt silicide layer 22a and polysilicon layer 14 of the gate electrode.

Minimum spacing X between the end of the element isolating film on the gate electrode side and the end of the bottom of hole 19a may appropriately be set according to heat treatment conditions (temperature, time and so on), but minimum spacing X is preferably 200 nm or less, more preferably 100 nm or less, further preferably 60 nm or less in terms of sufficient connection of polysilicon layer 14 of the gate electrode and contact plug 26a via cobalt silicide layer 22a.

As shown in FIG. 4(b4), cobalt silicide layer 22a and polysilicon layer 14 of the gate electrode may be connected by heating in a step after formation of contact plugs 26 and 26a. Normally, a plurality of insulating films such as an interlayer insulating film made of a silicon oxide film or the like and an etching stopping layer made of a silicon nitride film or the like are further formed on interlayer insulating film 18. The heat treatment for the silicide formation reaction of cobalt and silicon may be carried out at about 400 to 500° C., whereas these insulating films are formed under the temperature condition of about 700° C. Thus, the heat treatment for connecting cobalt silicide layer 22a and polysilicon layer 14 of the gate electrode may also be carried out in the step of forming the insulating films.

The thickness of the gate insulating film is preferably 10 nm or less in terms of sufficient connection of cobalt silicide layer 22a and polysilicon layer 14 of the gate electrode. The gate insulating film may be a laminated film including a silicon oxide film, silicon oxy-nitride film or any thereof. When the gate insulating film is a silicon oxy-nitride film, the thickness of the gate insulating film is preferably 5 nm or less.

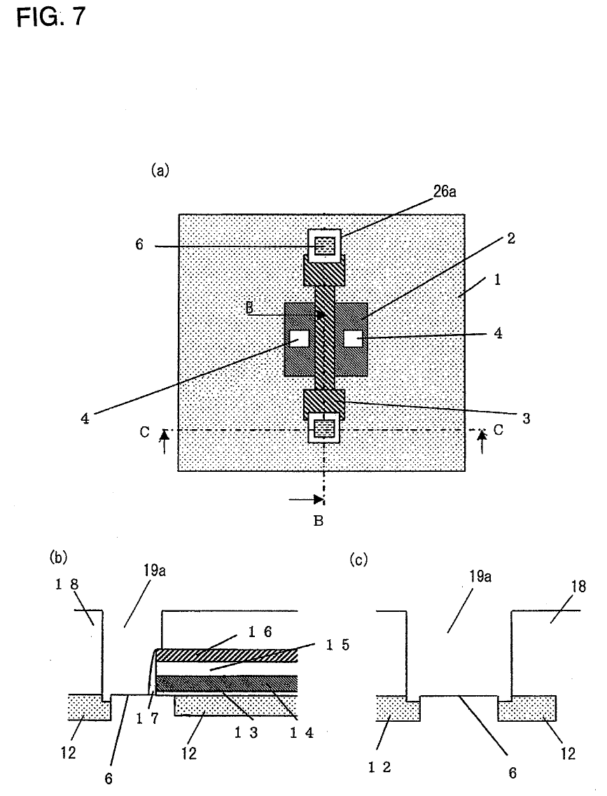

An alteration of the first embodiment will be described using FIGS. 7(a) to 7(c).

FIG. 7(a) is a schematic plan view of a unit element of an FET constituting the semiconductor device of this embodiment. This is different from the structure shown in FIG. 3 in a sense that the area of gate contact plug 26a on the flat surface of the substrate is greater than the area of the contact forming region.

FIG. 7(b) is a schematic sectional view taken along line B-B of FIG. 7(a), and FIG. 7(c) is a schematic sectional view taken along line C-C of FIG. 7(a).

Hole 19a is formed using an anisotropic dry etching method using a mask having an opening having an area larger than that of contact forming region 6. For the etching conditions of anisotropic dry etching, the etching speed for the silicon and silicon nitride films is lower than the etching speed for the silicon oxide film. Consequently, even if a position at which hole 19a for gate contact plug 26a is formed overlaps with the gate electrode, the gate electrode can be prevented from being etched.

The element isolating film 12 is relatively thick, and therefore if over-etching is carried out when forming the hole, a portion exposed in the hole is etched away to generate a step as shown in FIGS. 7(b) and 7(c), but a problem does not particularly arise.

As shown in FIGS. 7(b) and 7(c), in hole 19a, an exposed portion of the silicon substrate is surrounded by element isolating film 12 except for an area below the end portion of the gate electrode. That is, a region where gate contact plug 26a contacts the surface of the silicon substrate (hereinafter referred to as “plug contact region”) coincides with contact forming region 6 (except for a portion covered with the end portion of the gate electrode). In the structure shown in FIG. 3, contact forming region 6 is larger than the plug contact region. In FIG. 7(a), gate contact plug 26a is depicted as if contact forming region 6 could be seen through for the sake of explanation.

In this embodiment, in hole 19a, the exposed portion of the silicon substrate is surrounded by element isolating film 12 except for an area below the end portion of the gate electrode. Therefore, for cobalt diffused into the silicon substrate and diffused in a direction parallel to the substrate flat surface when silicon is reacted with cobalt by a heat treatment to form a cobalt silicide layer after forming a cobalt film in hole 19a, the amount of cobalt diffused into a silicon portion below the end portion of the gate electrode is large as compared to the first embodiment. As a result, connection of the cobalt silicide layer and the polysilicon layer of the gate electrode becomes easier.

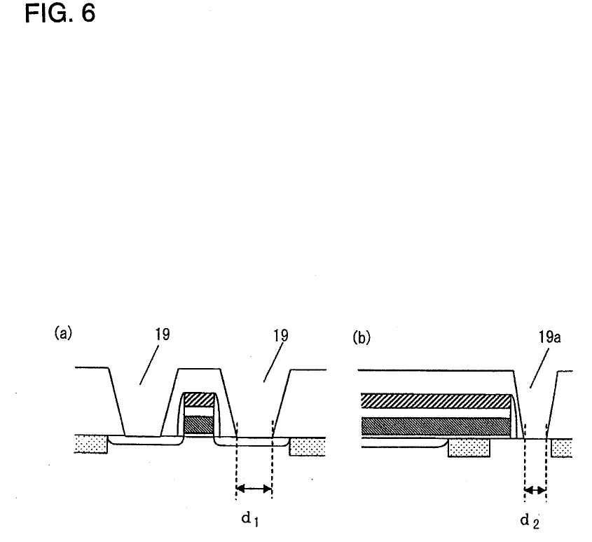

The second embodiment will be described in detail using FIG. 6.

FIGS. 6(a) and 6(b) correspond to FIGS. 4(a2) and 4(b2) of the first embodiment, respectively. In this embodiment, contact diameter d2 of hole 19a is smaller than contact diameter d1 of hole 19.

When a hole is formed in an interlayer insulating film using the anisotropic dry etching method, damage by dry etching is left on the surface of the substrate at the bottom of the hole. According to a chemical dry etching (CDE) method, this damage can be removed.

In this embodiment, for removing the damage layer at the bottom of hole 19 by dry etching, the silicon surface exposed at the bottom of the hole is removed by 10 nm using a CDE method under the conditions described below, and the damage layer at the bottom of hole 19a is left without being removed.

For the CDE method, a mixed gas of O₂/CF₄ may be used.

Since opening diameter d2 of hole 19a is smaller than opening diameter d1 of hole 19 and the aspect ratio of hole 19a is high, an etchant does not arrive at the bottom of hole 19a, and the damage layer is left at the bottom of hole 19a.

Opening diameter d1 of hole 19 can be equal to the opening diameter of hole 19 of the first embodiment, i.e. Φ140 nm, and opening diameter d2 of hole 19a can be Φ100 nm. For leaving the damage layer at the bottom of hole 19a, opening diameter d2 of hole 19a is preferably 150 nm or less, more preferably 100 nm or less. For leaving the damage layer at the bottom of the hole, the aspect ration is preferably 4 or more, more preferably 6 or more.

If a silicide formation reaction is carried out when there is no etching damage layer on the surface of the silicon substrate at the bottom of hole 19 and there is an etching damage layer on the surface of the silicon substrate at the bottom of hole 19a, the rate of the silicide formation reaction at the bottom of hole 19a increases as compared to a case where there is no etching damage layer. As a result, the silicide layer is easily formed and the amount of cobalt diffused increases, thus making it possible to connect the silicide layer and the polysilicon layer of the gate electrode more easily compared to the first embodiment.

The third embodiment will be described.

In this embodiment, the gate insulating film formed on contact forming region 6 is made to have a thickness smaller than that of the gate insulating film formed on the active region in the structure shown in FIG. 4(b1). The thickness of the gate insulating film formed on contact forming region 6 may be set to, for example, 5 nm whereas the thickness of the gate insulating film formed on the active region is 10 nm.

A structure in which the thickness of the gate insulating film varies depending on the region can be formed by a publicly known method known as a multi-oxide process. For example, by carrying out a process comprising a first oxide film forming step of forming an oxide film on a first region and a second region, a step of masking the second region and removing the oxide film on the first region, and a second oxide film forming step of forming an oxide films on the first region and the second region after removing the mask, an oxide film having different thickness on the first region and the second region can be obtained (in this case, the oxide film of the first region has a thickness greater than that of the oxide film of the second region). Such a multi-oxide process is disclosed in, for example, Japanese Patent Laid-Open No. 2004-39775 and Japanese Patent Laid-Open No. 2004-342656.

In the third embodiment, the thickness of the gate insulating film required to be broken by silicide formation is smaller than the thickness of the gate insulating films shown in the first and second embodiments, and therefore the silicide layer formed below the gate electrode via the gate insulating film can easily be connected to the gate electrode.

What is claimed is:

1. A method for production of a semiconductor device comprising: a silicon substrate;
an element isolating film provided on said silicon substrate;
an active region surrounded by said element isolating film;
a gate electrode provided on said active region via a gate insulating film and having a laminated structure including a polysilicon layer on the lower layer side and a metal layer on the upper layer side;
a diffusion layer provided on said active region on opposite sides of said gate electrode;
an interlayer insulating film provided over said silicon substrate;
a first plug filled in a first hole formed in said interlayer insulating film, and electrically connected to said gate electrode; and
a second plug filled in a second hole formed in said interlayer insulating film, and electrically connected to said diffusion layer,
said method comprising the steps of:
preparing a silicon substrate having an element isolating region, an active region and a contact forming region;
forming a gate electrode provided on said active region via a gate insulating film and extending so as to overlap with a portion of said contact forming region via an insulating film;
introducing an impurity into said active region to form a diffusion layer; forming an interlayer insulating film;
forming a first hole extending to another portion of said contact forming region and a second hole extending to said diffusion layer in said interlayer insulating film;
forming a metal film on at least the silicon substrate exposed surface of the bottom of the first hole and the second hole;
reacting said metal film with the silicon substrate by heating to form a metal silicide layer on said contact forming region and diffusion layer, and to connect said metal silicide layer formed on the contact forming region to the polysilicon layer lower surface side of the gate electrode extending portion
overlapping with a portion of the contact forming region; and
filling a conductive material in the first hole and the second hole to form a first plug contacting the metal silicide layer on said contact forming region and a second plug contacting the metal silicide on said diffusion layer.

2. A method for production of a semiconductor device comprising: a silicon substrate;
an element isolating film provided on said silicon substrate;
an active region surrounded by said element isolating film;
a gate electrode provided on said active region via a gate insulating film and having a laminated structure including a polysilicon layer on the lower layer side and a metal layer on the upper layer side;
a diffusion layer provided on said active region on opposite sides of said gate electrode;
an interlayer insulating film provided over said silicon substrate;
a first plug filled in a first hole formed in said interlayer insulating film, and electrically connected to said gate electrode; and
a second plug filled in a second hole formed in said interlayer insulating film, and electrically connected to said diffusion layer,
said method comprising the steps of:
preparing a silicon substrate having an element isolating region, an active region and a contact forming region;
forming a gate electrode provided on said active region via a gate insulating film and extending so as to overlap with a portion of said contact forming region via an insulating film;
introducing an impurity into said active region to form a diffusion layer; forming an interlayer insulating film;
forming a first hole extending to another portion of said contact forming region and a second hole extending to said diffusion layer in said interlayer insulating film;
forming a metal film on at least the silicon substrate exposed surface of the bottom of the first hole and the second hole;
reacting said metal film with the silicon substrate by first heating to form a metal silicide layer on said contact forming region and diffusion layer;
filling a conductive material in the first hole and the second hole to form a first plug contacting the metal silicide layer on said contact forming region and a second plug contacting the metal silicide on said diffusion layer; and
connecting the metal silicide layer formed on the contact forming region to the polysilicon layer lower surface side of the gate electrode extending portion overlapping with a portion of the contact forming region by second heating.

3. The method for production of a semiconductor device according to claim 1, wherein said metal film is a cobalt film, and said metal silicide layer is a cobalt silicide layer.

4. The method for production of a semiconductor device according to claim 1, wherein, in the step of forming the first hole and the second hole, the inner diameter of the first hole is made to be smaller than the inner diameter of the second hole so that an etching damage layer generated at the time of forming the first hole is left on the bottom of the hole and an etching damage layer on the bottom of the second hole generated at the time of forming the hole is removed in a chemical dry etching step that is subsequently carried out, and
the method further comprising the step of carrying out chemical dry etching to leave the etching damage layer on the bottom of the first hole and remove the etching damage layer on the bottom of the second hole after formation of the first hole and the second hole.

5. The method for production of a semiconductor device according to claim 1, wherein while said gate insulating film is formed on the active region, said insulating film is formed on said contact forming region, and said gate electrode extending so as to overlap with a portion of the contact forming region is formed via the insulating film.

6. The method for production of a semiconductor device according to claim 1, wherein the insulating film formed on said contact forming region is formed so as to be thinner than the gate insulating film formed on said active region, and said gate electrode extending so as to overlap with a portion of the contact forming region is formed via the thin insulating film.

7. The method for production of a semiconductor device according to claim 2, wherein said metal film is a cobalt film, and said metal silicide layer is a cobalt silicide layer.

8. The method for production of a semiconductor device according to claim 2, wherein, in the step of forming the first hole and the second hole, the inner diameter of the first hole is made to be smaller than the inner diameter of the second hole so that an etching damage layer generated at the time of forming the first hole is left on the bottom of the hole and an etching damage layer on the bottom of the second layer generated at the time of forming the hole is removed in a chemical dry etching step that is subsequently carried out, and
the method further comprising the step of carrying out chemical dry etching to leave the etching damage layer on the bottom of the first hole and remove the etching damage layer on the bottom of the second hole after formation of the first hole and the second hole.

9. The method for production of a semiconductor device according to claim 2, wherein while said gate insulating film is formed on the active region, said insulating film is formed on said contact forming region, and said gate electrode extending so as to overlap with a portion of the contact forming region is formed via the insulating film.

10. The method for production of a semiconductor device according to claim 2, wherein the insulating film formed on said contact forming region is formed so as to be thinner than the gate insulating film formed on said active region, and said gate electrode extending so as to overlap with a portion of the contact forming region is formed via the thin insulating film.

11. A method for production of a semiconductor device comprising: forming an active region surrounded by isolating film in a silicon substrate;
forming a gate insulating film on the surface of the active region; forming a gate electrode covering a portion of an edge of the active region via the gate insulating film;
forming an interlayer insulating film over the gate electrode and the active region;
forming a hole in the interlayer insulating film to expose a portion of the surface of the active region, and not to expose the gate electrode;
forming a metal film on the surface of the active region which is exposed at a bottom of the hole;
reacting said metal film with the silicon substrate by heating to form a metal silicide layer, and to connect said metal silicide layer to the gate electrode by penetrating the gate insulating film under the gate electrode;
filling a conductive material in the hole to form a contact plug for contacting with the gate electrode via the silicide layer on the active region.

12. The method for production of a semiconductor device according to claim 11, wherein said gate electrode comprises a laminate structure including
a polysilicon layer and a metal layer on the polysilicon layer, and the metal silicide layer connects to the polysilicon layer.

13. The method for production of a semiconductor device according to claim 12, wherein said metal film is a cobalt film, and said metal silicide layer is a cobalt silicide layer.

14. The method for production of a semiconductor device according to claim 11, further comprising a step of chemical dry etching for removing a damage layer after forming the hole in the interlayer insulating film, wherein an aspect ratio of the hole is higher for removing a damage layer of the surface of the active region which is exposed at the bottom of the hole, and the damage layer remains at the surface of the active region which is exposed at the bottom of the hole.
